(19) United States
(12) Patent Application Publication
(10) Pub. No.: US 2010/0282290 A1
(43) Pub. Date: Nov. 11, 2010

(54) PHOTOVOLTAIC UNIT COMPRISING A MATRIX OF FRAMELESS SOLAR MODULES

(75) Inventors: Sascha Oliver Schwarze, Berlin (DE); Maik Schaefer, Berlin (DE)

Correspondence Address: Leydig, Voit & Mayer, Ltd. (Frankfurt office), Two Prudential Plaza, Suite 4900, 180 North Stetson Avenue, Chicago, IL, 60601-6731, US

(73) Assignee: SOLON SE, Berlin (DE)

(21) Appl. No.: 12/744,205

(22) PCT Filed: Nov. 6, 2008
(86) PCT No.: PCT/DE2008/001834

§ 371 Date: May 21, 2010

(30) Foreign Application Priority Data
Nov. 21, 2007 (DE) 10 2007 056 600.1

(51) Int. Cl. H01L 31/042

(52) U.S. Cl. 136/244

(57) ABSTRACT

A photovoltaic unit includes a matrix having a plurality of frameless rectangular solar modules, and at least one module rail disposed on an underside of each solar module. Each of the at least one module rail is coupled to a substrate rail, which is releasably connected to a substrate. Each of the at least one module rail and the at least one substrate rail has a guide rail running parallel to an edge of the respective solar module on at least a longitudinal side of the respective rail facing towards an edge region of the solar module. The guide rails on the module and substrate rails are releasably connected to each other by at least one connecting element. A spacer gap of sufficient width for operating the connecting element is provided between adjacent solar modules of the plurality of frameless rectangular solar modules.

The invention relates to a photovoltaic unit with a matrix made up of frameless rectangular solar modules which have at least two opposite module rails in the edge region on their underside, by means of which they are releasably connected to a substrate.

Among renewable energy sources, photovoltaics offers the widest range of possible applications on account of the modular construction of photovoltaic units from individual solar modules. The main application today is found in the area of consumer use, that is to say, photovoltaic units are used for converting solar energy into electrical energy. To this end, the photovoltaic units must be installed on substrates which have access to sunlight. Here, what is meant is generally open spaces or roofs or facades of buildings. In particular, attention must be paid during installation to securing the solar modules against lifting off due to wind forces. Frameless solar modules show a particularly elegant uniform appearance and are particularly easy to maintain owing to a lack of shoulders, but harder to mount than framed solar modules, for which the frame can be used as a mounting element.

### PRIOR ART

The fixing of rectangular frameless solar modules, which are sealed into a holding frame, is known from DE 10 2005 050 884 A1. Module rails are integrated in these solar modules, by means of which module rails, the solar module is screwed to the substrate. A direct connection of the module rails to the solar module is not provided. It is known from DE 10 2004 041 279 A1 to connect a solar module to a module plate by means of adhesive bonding or hook and loop fastening via a multiplicity of knobs distributed over the surface of the solar module. To connect the module plates to one another to form a photovoltaic unit, the module plates have guide rails with a dovetail profile at the side. It is known from DE 10 2005 057 468 A1 to support a solar module with a lightweight building board which carries module rails in the edge region. In this case, the module rails can be constructed as a peripherally closed support profile (extruded profile). Specially formed grooves are located in the module rails, which grooves engage into connecting elements (not explained or illustrated in any more detail) which correspond with the shape of the grooves. For installation, the solar modules must be pushed into the fixing elements one after the other using the module rails.

It is known from DE 102 33 973 A1 to clamp frameless solar modules directly into connecting elements which engage as displaceable sliders into a substrate rail and consist of two fixing plates which can be screwed together, between which fixing plates, the solar module is clamped. Although installed solar modules can be removed individually by unscrewing the screw connection, a series of losable installation parts then results. At least three connecting elements—two in the edge regions, one in the middle—are provided per solar module, wherein the connecting elements should be arranged with a spacing of at most 0.6 m to one another. Module rails are not provided on the solar modules, so that large forces are introduced into the solar module at certain points by means of the clamping via the connecting elements. In the plan view onto the solar module, the connecting elements are additionally visible and effect a corresponding shadowing of the solar modules.

Furthermore, a fixing device for attaching plates to a wall or ceiling is known from DE 89 01 194 U1, which fixing device consists of at least one structural girder and plate holders which can be fixed thereto, wherein each plate holder has the same profile cross section as the structural girder and the plate holder is installed in a position on the structural girder which is turned through 180°.

The profile cross section shows a U-shaped and an opposite L-shaped transverse side. Both sides have reinforcing ribs. For coupling, structural girders and plate holders are initially placed one inside the other and then displaced laterally and subsequently pushed completely one inside the other, so that the profiles engage into one another and the rails are secured against lateral displacement. A secure, but releasable connection of the two elements which prevents a pulling apart of the rails (direction orthogonal to lateral displacement), is not provided, however.

The present invention proceeds from DE 40 14 200 A1 as the closest prior art. This publication discloses a generic photovoltaic unit with a plurality of rectangular solar modules which are arranged in rows and columns in the manner of a matrix. The solar modules preferably consist of a multiplicity of solar cells which are connected to one another and embedded in a laminate. The laminate also accommodates the incoming and outgoing electrical/electronic wiring of the solar cells. At least two opposite module rails are adhesively bonded to the underside of the solar modules, which module rails can be releasably screwed to a substrate, so that the solar modules are securely connected to the substrate. A corresponding installation outlay results in this case, however. Adhesive-filled sealing joints are provided at the transition points between two solar modules or between one solar module and an equivalent pane of glass, which sealing joints do not allow access to the module rails or their fixing to the substrate, so that simple uninstallation of the solar modules is not possible.

### OBJECT

Starting from the above-explained generic photovoltaic unit, the OBJECT for the present invention is therefore to be seen in specifying a developed photovoltaic unit of this type, which has particularly simply constructed and operable means for fixing the solar modules to the substrate. The solar modules should be particularly simple to install and uninstall. In this case, individual solar modules in particular should be removable from the matrix of the photovoltaic unit for replacement, cleaning or maintenance purposes without large outlay and without a relatively large impairment of the adjacent solar modules. In this case, the installation means should not disrupt the homogeneous appearance of a photovoltaic unit made from frameless solar modules and should not cause any shadowing of the solar modules. The SOLUTION for this object is to be drawn from the main claim. Advantageous developments of the invention are shown in the sub-claims and are explained in more detail in the following in connection with the invention.

The photovoltaic unit according to the invention has a matrix made up of frameless rectangular solar modules which can be releasably connected to a substrate by means of module rails on their underside. In this case, releasably connected substrate rails are provided on the substrate, into which rails the module rails are coupled. Module rail and substrate rail essentially show the same cross section with a U-shaped and an opposite L-shaped transverse side and are arranged in positions which are rotated by 180° relative to one another. With these features, module rails and substrate rails of the invention conform with the structural girder and the plate holder of the fixing device known from DE 89 01 194 U1. Initially, only securing against lateral displacement of the solar modules results by means of this design. Securing against being pulled out, which corresponds to a lifting off of the solar modules under wind loading does not exist yet. For securing against this pulling out/lifting off, module and substrate rail in the invention therefore have a guide rail running parallel to the solar module/substrate in each case on at least the longitudinal sides which face the edge regions of the solar modules. These are releasably connected to one another by means of at least one connecting element. In this case, a spacer gap of sufficient width for operating the connecting element is provided between adjacent solar modules. In the invention, provision is therefore additionally made, in addition to the securing against displacement, for a secure but releasable connection between the photovoltaic unit and substrate, as a result of which a lifting off of the solar modules on the basis of wind forces is reliably prevented. In spite of this, the highly aesthetic sight of the frameless solar modules in their regular matrix arrangement with structuring spacer gaps between the solar modules is not disturbed. All of the connecting elements are arranged underneath the solar modules and do not shadow, they are simple to reach and to operate. Individual solar modules can be taken out of the matrix and inserted again without any problems in spite of this by means of the individual assignment of the connecting elements.

An already good fixing of each solar module results if at least one connecting element is advantageously provided per solar module in the two edge regions of the module rails. Additionally at least one further connecting element can be provided per solar module in the middle of the module rails. Multiple fixing per module rail particularly makes sense in the case of large solar modules, so that wind forces which arise do not obtain any areas to act upon which are too large. Furthermore, the basic task of the connecting element is to be seen in the secure connection of module rail and substrate rail, so that these form a secure composite and the solar module does not lift off the substrate under the action of wind. Thus, all designs for the connecting element in combination with the module and substrate rail which fulfill this purpose are suitable. The connecting element in this case advantageously has means for securing with respect to the module rail and substrate rail. In this case, it can be a screw or rocker arm device.

The connecting element is particularly advantageously constructed as a slider which can be displaced on the guide rails, wherein the spacer gap between the solar modules for operating the slider only has a width of such a type that a single displacement tool can engage through it. It is reliably ensured by means of this design configuration that the connecting element is always available to the installer and does not have any releasable parts. It is pushed onto the coupled module and substrate rails and, in the case of uninstallation of a solar module, is only pushed over into the region of adjacent solar modules (after slight displacement of the sliders provided there) and parked there. A loss of the connecting element or individual parts thereof is thereby excluded. Furthermore, it is not necessary in the case of the slider configuration that the connecting element is placed onto the rail system from the front and fixed there, so that the gap width between the solar modules can be dimensioned smaller accordingly. It just has to be dimensioned to be so wide that an offset displacement tool fits through it. In this case, it can be a simple bent rod. The bend is necessary in order to reach the connecting element which is set back behind the solar module edge. The design becomes even simpler if no actuatable means are used for securing the connecting element, but rather if the means for securing the displaceable slider with respect to the substrate rail is constructed as a spring shackle, which presses against the module and substrate rails. Although the displacement must then take place against the spring force, that is possible without any problems in the case of a corresponding configuration of the displacement tool, as the spring force to be overcome is not very large.

The displaceability of the slider on the rails can in turn be achieved in the widest variety of ways from a design point of view. For example, pins on the connecting element can engage in corresponding grooves in the rails. Advantageously, the guide rails can have oblique undercuts, wherein the guide rails connected to one another in each case by means of the connecting element have opposing oblique undercuts which form a dovetail guide with the corresponding oblique undercuts on the connecting element. A guide of this type can be produced relatively simply without additional elements and ensures a good accuracy of fit. A slight displacement of the slider is possible with its exact orientation and positioning and module and substrate rails are additionally pushed against one another by means of the oblique undercuts with a defined force.

The connecting elements are preferably arranged in the edge regions of the solar module/module rails, so that the connecting elements of adjacent solar modules can face one another. Such mutually opposite connecting elements of adjacent solar modules can advantageously be connected to one another or constructed in one piece. Although the displacement can then only take place in pairs, an advantageous supporting and strengthening of the solar modules with respect to one another results. Furthermore, the solar modules are fixed to a substrate. Advantageously, mutually opposite substrate rails of adjacent solar modules can instead be fixed to the substrate by means of a common fixing rail. All solar modules in a row or column can then be fixed with one rail. Advantageously, simple screw connections which engage into the substrate can be used for this purpose. In this case, the substrate can preferably be constructed as a substructure, lightweight building board, sloping or flat roof or facade. In particular, a simple installation of the solar modules is possible directly on a substructure on the wooden roof truss of a sloping roof.

Finally, the module rails can advantageously be arranged in sections or continuously on all four sides of each solar module. The coupling of the module rails into the substrate rails always takes place in accordance with the same procedure. First, the rails are placed perpendicularly one inside the other, then the solar modules and therefore the module rails are displaced laterally and finally pushed completely one inside the other, so they are secured against further lateral displacement. If module rails are located on all four sides of the solar module, the module rails coupled into all four or continuous substrate rails are first displaced in the one direction, so that they couple with the substrate rails lying in this direction, and then displaced in the other direction, so that they also couple with these substrate rails, finally the module plate is guided downwards and the module and substrate rails are thereby completely pushed one inside the other. The connection of the module rails with the underside of the solar modules can in turn be achieved differently from a design point of view. Simple adhesive bonding, for example with Terrostat is advantageous. In this case, an elastic closure rail can also be interposed for compensating thermal expansions. Further design details for the photovoltaic unit according to the invention can be drawn from the following special description section.

### EXEMPLARY EMBODIMENTS

Embodiments of the photovoltaic unit according to the invention with a connecting element, which protects against lifting off, between module and substrate rails are explained in more detail in the following on the basis of the schematic figures for further understanding of the invention. In the figures:

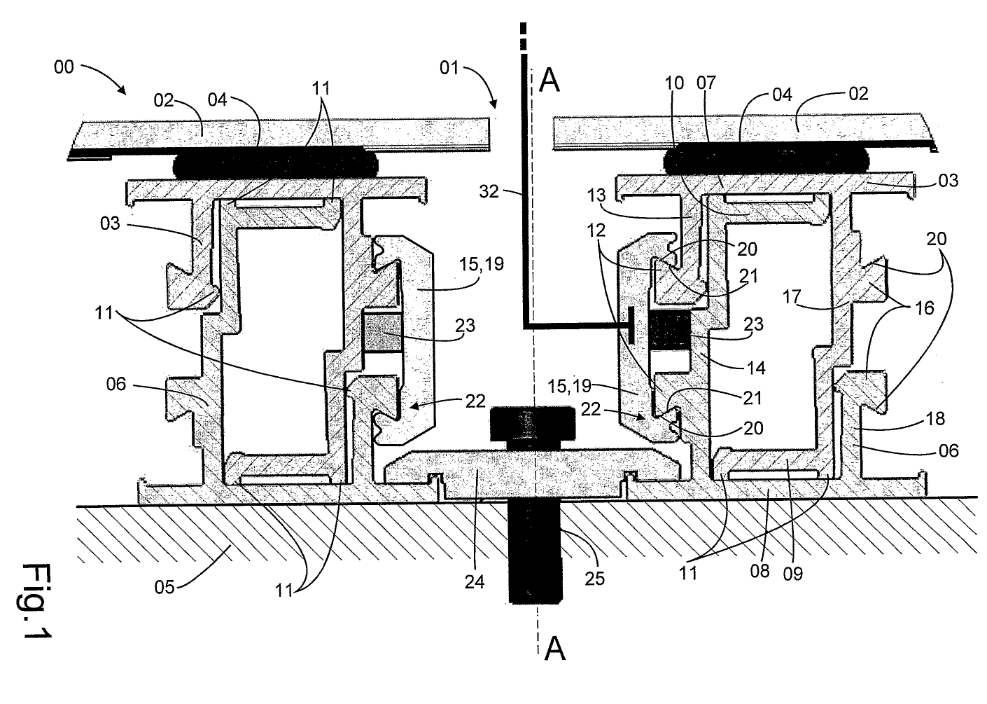

FIG. 1 shows the cross section of the photovoltaic unit according to the invention in the region of the spacer gap between two solar modules;

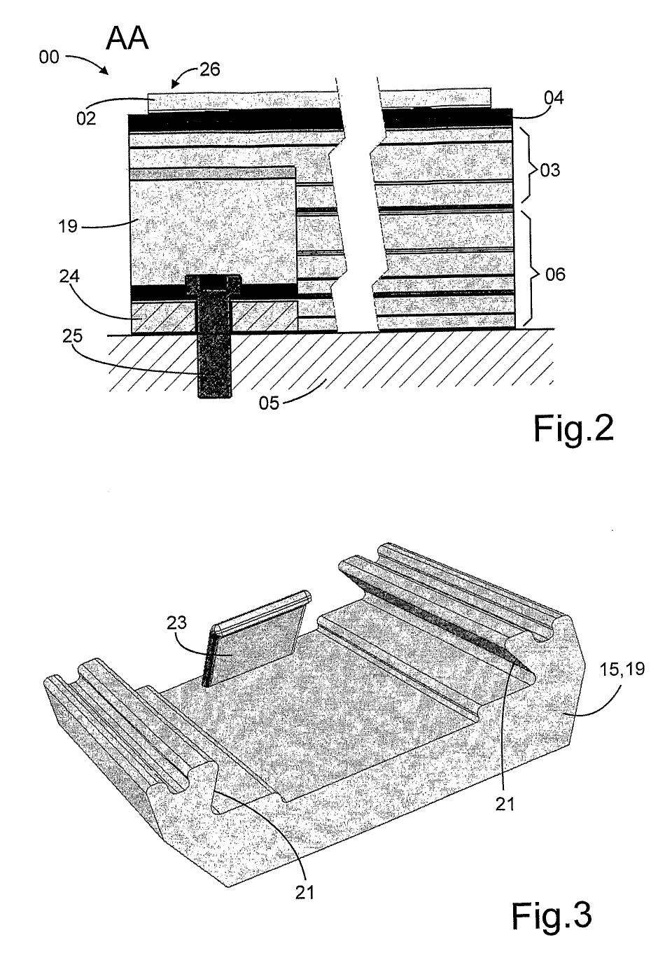

FIG. 2 shows a sectional representation onto a solar module in the region of the spacer gap;

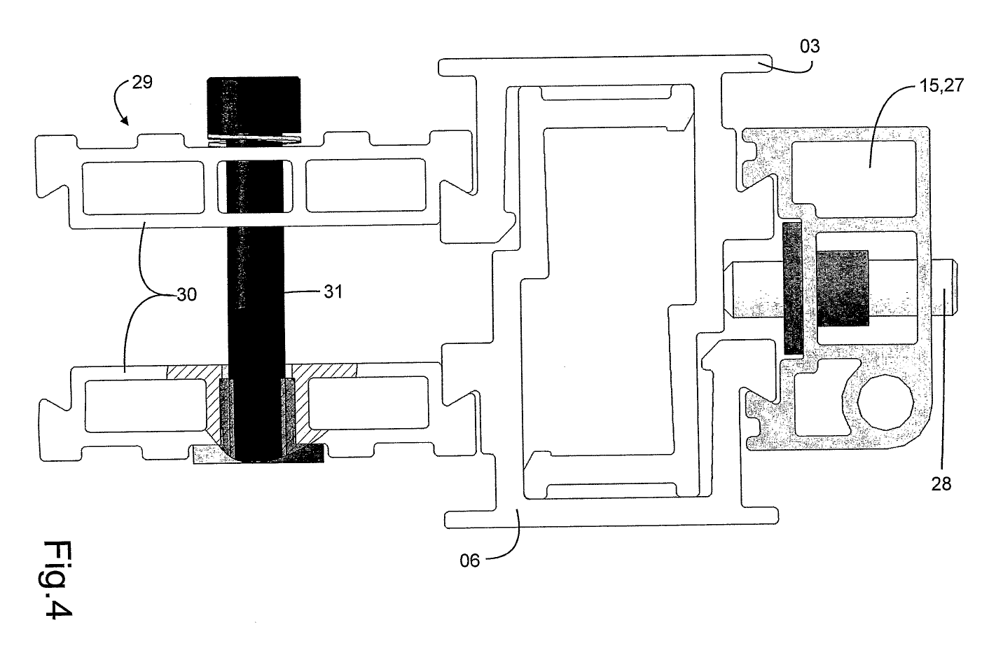

FIG. 3 shows a slider in detail; and

FIG. 4 shows two alternative constructions of sliders.

FIG. 1 shows a detail from a photovoltaic unit 00 according to the invention in cross section in the region of a spacer gap 01 between two frameless rectangular solar modules 02 (shown cut away from the side), which are arranged in a regular matrix, so that a harmonic undisturbed appearance of the photovoltaic unit results. A module rail 03 is in each case arranged on the underside in the edge regions of the solar modules 02 which face one another. In the exemplary embodiment shown, the module rails 03 are adhesively bonded to the solar modules 02 by means of elastic glue joints 04. The solar modules 02 are releasably but securely connected to a substrate 05 by means of the module rails 03. In this case, the substrate 05 is a substructure, lightweight building board, sloping or flat roof or facade. Both horizontal and vertical installation of the solar modules 02 is possible.

The module rails 03 are in each case releasably coupled to substrate rails 06 for connection of the solar modules 02 to the substrate 05. Module rail 03 and substrate rail 06 are arranged in positions which are rotated by 180° relative to one another and essentially have the same cross section. The transverse side 07 of the module rail 03 adjacent to the solar module 02 and the transverse side 08 of the substrate rail 06 adjacent to the substrate 04, respectively, is of L-shaped construction. The respectively opposite transverse sides 09, 10 have a U-shaped course. To avoid static overdeterminations between the module and substrate rails 03, 06 which lie on top of one another, the adjacent transverse sides 07, 08 and the open ends of the opposite transverse sides 09,10 are in each case provided with brackets 11. Due to the construction of the module and substrate rails 03, 06 and also due to their diametrically rotated arrangement with respect to one another, during the installation of the solar modules 02, they can first be placed one inside the other, then displaced laterally and finally pushed completely one inside the other. In the position in which they are pushed completely one inside the other, they—and therefore the solar modules 02—are secured against a lateral displacement. A pulling apart of module rails 03 and substrate rails 06—and therefore a lifting off of the solar modules 02—is still possible, however.

For avoiding the pulling apart of module rails 03 and substrate rails 06, these have guide rails 12 running parallel to the solar module 02 or to the substrate 05 on at least the longitudinal sides 13, 14 which face the spacer gap 01. By means of the two guide rails 12 on the longitudinal sides 13, 14 of the module and substrate rail 03, 06 which face the spacer gap 01 these are then releasably connected to one another by means of at least one connecting element 15. In this case, the spacer gap 01 between the adjacent solar modules 02 has a width sufficient for operating the connecting element 15. In the selected exemplary embodiment, the module rail 03 and the substrate rail 06 have exactly the same profile, as a result of which, the production of the rails, for example by means of extrusion and their procurement is substantially facilitated. The module rail 03 and substrate rail 06 therefore also have guide rails 16 on the longitudinal sides 17, 18 facing away from the spacer gap, in addition to the guide rails 12 on the longitudinal sides 13, 14 facing the spacer gap 01. These are not used to connect the module rail 03 and substrate rail 06 however in the exemplary embodiment shown, as they are located inaccessibly underneath the solar module 02. For mutual guiding, the module rail 03 and substrate rail 06 likewise have brackets 11 on their facing longitudinal sides 13, 18.

In the exemplary embodiment shown, the connecting element 15 is constructed as a slider 19 which can be displaced on the guide rails 13, 14. To this end, the guide rails 13, 14 have oblique undercuts 20. The guide rails 13, 14 connected to one another by means of the connecting element 15 have opposite oblique undercuts 20. Together with oblique undercuts 21 on the displaceable slider 19, the oblique undercuts 20 on the module and substrate rails 03, 06 form a dovetail guide 22. In the case of the displaceable slider 19 as a connecting element 15, the spacer gap 01 between the solar modules 02 for displacing the slider 19 can be very narrow. It must only be possible for a single displacement tool 32 of a type similar to a screw driver to be able to engage through it (shown dashed in FIG. 1). To secure the displaceable slider 19 with respect to the substrate rail 06, a spring shackle 23 is provided on the slider 19 in the exemplary embodiment selected. In the lower region of the mutually opposite substrate rails 06 of adjacent solar modules 02, a fixing rail 24 which engages over the substrate rails 06, which fixing rail can be screwed to the substrate 05 by means of a screw connection 25. As a result, the secure composite linkage of the solar modules 02 to the substrate 05 is closed, and it is reliably ensured that the solar modules 02 cannot lift off from the substrate 05 by means of wind force.

FIG. 2 shows a cut away sectional illustration in the spacer gap 01 with a view of the right half of the photovoltaic unit 00 (section AA according to FIG. 1). The solar module 02, the glue joint 04, the module rail 03, the slider 19, the substrate rail 06, the fixing rail 24 and the screw connection 25 for the screw connection in the substrate 05 can be recognized. The width of the slider 19 and its positioning in the edge region 26 of the solar module 02 can be seen. In the exemplary embodiment selected, the rails 03, 06 and the slider 19 laterally project slightly beyond the solar module 02, without impairing the homogeneous overall impression of the frameless solar modules 02 in the plan view, however.

FIG. 3 shows a perspective view of the slider 19. The oblique undercuts 21 for forming the dovetail guide 22 and the spring shackle 23 for bracing the 5 slider 19 against the substrate rail 06 can be seen (cf. FIG. 1).

FIG. 4 shows an alternative embodiment of a slider 27 on the right with a screw connection 28 for bracing the slider 27 with respect to the module rail 03. A double slider 29 for the simultaneous connection of the rail systems of two solar modules 02 is shown on the left. The double slider 29 consists of two identical guide pieces 30, which are connected to one another by means of a screw connection 31. Both alternative sliders 27, 29 would be to be arranged in the region of the spacer gap 01.

### REFERENCE LIST

00 Photovoltaic unit
01 Spacer gap
02 Frameless rectangular solar module
03 Module rail
04 Glue joint
05 Substrate
06 Substrate rail
07 Transverse side of 03 adjacent to 02
08 Transverse side of 06 adjacent to 05
09 Transverse side of 03 opposite 07
10 Transverse side of 06 opposite 08
11 Bracket
12 Guide rail facing 01
13 Longitudinal side of 03 facing 01
14 Longitudinal side of 06 facing 01
15 Connecting element
16 Guide rail facing away from 01
17 Longitudinal side of 03 facing away from 01
18 Longitudinal side of 06 facing away from 01
19 Displaceable slider
20 Oblique undercut on 12, 16
21 Oblique undercut on 19
22 Dovetail guide
23 Spring shackle
24 Fixing rail
25 Screw connection of 24
26 Edge region of 02
27 Slider (alternative embodiment)
28 Screw connection of 27
29 Double slider
30 Guide piece
31 Screw connection of 29
32 Displacement tool

1-12. (canceled)

13. A photovoltaic unit comprising:
a matrix including a plurality of frameless rectangular solar modules; and
at least one module rail disposed on an underside of each solar module, each of the at least one module rail being coupled to a substrate rail, the substrate rail being releasably connected to a substrate,
wherein the at least one module rail and the at least one substrate rail each have a substantially similar cross section rotated by 180° with respect to each other, with a U-shaped transverse side adjacent to one of the respective solar module and the substrate and an opposite L-shaped transverse side, each of the at least one module rail and the at least one substrate rail having a guide rail running parallel to an edge of the respective solar module on at least a longitudinal side of the respective rail facing towards an edge region of the solar module,
wherein the guide rails on the module and substrate rails are releasably connected to each other by at least one connecting element, and
wherein a spacer gap of sufficient width for operating the connecting element is provided between adjacent solar modules of the plurality of frameless rectangular solar modules.

14. The photovoltaic unit according to claim 13, wherein at least one connecting element is provided for each solar module in a first and second edge regions of the solar module.

15. The photovoltaic unit according to claim 14, wherein at least one further connecting element is provided for each solar module in a middle section of the solar module.

16. The photovoltaic unit according to claim 13, wherein the connecting element includes a securing device configured to secure the connecting element with respect to at least one of the module and substrate rails.

17. The photovoltaic unit according to claim 13, wherein the connecting element includes a slider displaceable along the guide rails of the module and substrate rails.

18. The photovoltaic unit according to claim 17, wherein the spacer gap between the adjacent solar modules is configured to operate the slider and has a width suitable for a displacement tool to engage therethrough.

19. The photovoltaic unit according to claim 16, wherein the securing device includes a spring shackle.

20. The photovoltaic unit according to claim 13, wherein the guide rails of the module and substrate rails have opposing oblique undercuts when the module and substrate rails are connected to each other by the connecting element.

21. The photovoltaic unit according to claim 20 wherein the connecting element has oblique undercuts corresponding to the oblique undercuts of the guide rails.

22. The photovoltaic unit according to claim 21, wherein the oblique undercuts on the guide rails form a dovetail guide with corresponding oblique undercuts on the connecting element.

23. The photovoltaic unit according to claim 13, wherein mutually opposite connecting elements of adjacent solar modules are connected to each other.

24. The photovoltaic unit according to claim 13, wherein mutually opposite connecting element of adjacent solar modules are constructed in one piece.

25. The photovoltaic unit according to claim 13, wherein mutually opposite substrate rails of adjacent solar modules are affixed to the substrate by a common fixing rail.

26. The photovoltaic unit according to claim 13, wherein the at least one module rail includes a plurality of module rails disposed in sections or continuously on all sides of each solar module.

27. The photovoltaic unit according to claim 13, wherein the at least one module rail is adhesively bonded to the underside of the corresponding solar module.

28. The photovoltaic unit according to claim 13, wherein the substrate includes at least one of a substructure, a building board, a roof, and a facade.
